(19) United States
(12) Patent Application Publication
(10) Pub. No.: US 2019/0189700 A1
(43) Pub. Date: Jun. 20, 2019

(54) TOUCH DISPLAY DEVICE

(71) Applicant: Wuhan China Star Otpoelectonics Semiconductor Technology Co., Ltd., Wuhan (CN)

(72) Inventor: Xiaoliang FENG, Wuhan (CN)

(21) Appl. No.: 15/911,622

(22) Filed: Mar. 5, 2018

Related U.S. Application Data
(63) Continuation of application No. PCT/CN2018/073345, filed on Jan. 19, 2018.

(30) Foreign Application Priority Data
Dec. 19, 2017 (CN) 201711376827.2

(51) Int. Cl. H01L 27/32; G06F 3/041; G06F 3/044; H01L 51/52

(52) U.S. Cl. CPC H01L 27/323; G06F 3/0412; G06F 2203/04111; H01L 51/5253; G06F 2203/04103; G06F 3/044

(57) ABSTRACT

A touch display device is provided. The display panel includes a substrate; an anode positioned on the substrate; a touch electrode structure positioned on the substrate, the touch electrode structure is insulating with the anode; a planar layer positioned on the anode, the touch electrode structure and the substrate, the planar layer has a hole for exposing the anode; an OLED element positioned on the anode; a cathode positioned on the OLED element; and a package positioned on the cathode and the planar layer. This disclosure could reduce complex manufacturing while positioned the touch electrode structure in the OLED display device, and also reduce thickness of the touch display device.

### RELATED APPLICATIONS

The present application is a National Phase of International Application Number PCT/CN2018/073345, filed Jan. 19, 2018, and claims the priority of China Application No. 201711376827.2, filed Dec. 19, 2017.

### FIELD OF THE DISCLOSURE

The disclosure relates to a touch display technical field, and more particularly to a touch display device.

### BACKGROUND

With fast development of the display technology, people have more and more standard for display device, and property of high resolution, high colorful, fast response also cause the development of the display technology toward to high, strong, fast and thin. Semiconductor element technology is also fast development as a display problem solving solution of Organic Light Emitting Diode (OLED). In the existing technology, OLED display has self-luminous, fast response, wide view angle, suitable flexible substrate, such that could apply to cell phone, television, computer and some regulatory electric device, it also could used for virtual reality (VR) device, watch, wearable device, even though could used for bendable, flexible display filed. OLED display is widely used so that became one of the feature mainstream display technologies. Hence, the development and the research of the OLED is became core of feature display market for big panel manufacturing company.

With the development of display technology, the touch display device is more and more popular, especially for middle/smaller size display device. From the beginning, the touch and the display is two independently technology (which is Out Cell Touch technology, such as FF (Film to Film), GF (Glass to Film), GG (Glass to Glass), OGS (One Glass Solution)) and the display device has touch function which needs to pasting the touch panel and display panel, but there will causes complexity manufacture and thick display device, it's not fever to thin the product. Therefore, gradually developing the Oncell, Incell touch technology, these two technologies are greatly decrease complexity manufacture, and significant help to thin the display device, and it does not need to construct another factory for combine the display and touch. Therefore, this technology getting greatly development.

However, with the OLED technology is developing and become mainstream technology of the display, especially appear the flexible technology, touch technology has another bottlenecks. Generally, Oncell technology could solve the problem of touch panel apply to the OLED, but the low temperature manufacture, less water process limited the touch applicable range, the product yield and property are also be effected. The problem of Incell technology is that between the Incell process and OLED manufacture process, and hard to significant develop. Hence, the problem need to solve is that how to implant the Incell technology into OLED display device.

### SUMMARY

A technical problem to be solved by the disclosure is to provide a touch display device for implanting the touch electrode structure into the OLED display device.

An objective of the disclosure is achieved by following embodiments. In particular, a touch display device comprising a substrate: an anode positioned on the substrate; a touch electrode structure positioned on the substrate, the touch electrode structure is insulating with the anode; a planar layer positioned on the anode, the touch electrode structure and the substrate, the planar layer has a hole for exposing the anode; an OLED element positioned on the anode; a cathode positioned on the OLED element; and a packaging layer positioned on the cathode and the planar layer.

In an embodiment, a plurality of the touch electrode structure is provided, the plurality of the touch electrode structure is arranges parallel in row direction, and each of the touch electrode structures is extending in column direction.

In an embodiment, each of the touch electrode structures comprising a first conducting main strip extending along in column direction; a second conducting main strip extending along in column direction and parallel to the first conducting main strip; a first conducting branch strip extending along in row direction and connecting to the first conducting main strip; and at least two second conducting branch strips extending along in row direction and connecting to the second conducting main strip, and at least one of the first conducting branch strip is positioned between two of adjacent second conducting branch strips.

In an embodiment, each of the touch electrode structure has a plurality of the second conducting main strip, a plurality of the second conducting main strip is parallel along the column direction, and at least one of the first conducting branch strip is positioned between two of adjacent second conducting branch strips which connecting to each of the second conducting main strips.

In an embodiment, the first conducting main strip comprises a plurality of sensing pad arranged in column direction and a bridge connector for connecting in cascade with the sensing pad.

In an embodiment, the second conducting main strip comprises a plurality of sensing pad arranged in column direction and a bridge connector for connecting in cascade with the sensing pad.

In an embodiment, the first conducting branch strip comprises a sensing pad and a bridge connector for connecting the sensing pad to the first conducting main strip.

In an embodiment, the second conducting branch strip comprises a sensing pad and a bridge connector for connecting the sensing pad to the second conducting main strip, the sensing pad of the first conducting branch strip is positioned between two of adjacent correspondingly the second conducting branch strips.

In an embodiment, the sensing pad is one of rectangular, grid, rhombus, triangle, regular pentagon, regular hexagon, octagon.

In an embodiment, all of the second conducting main strips of the touch electrode structures are arranged in array; the touch display device further comprises a plurality of switches, each of the switches corresponding to one of the touch electrode structure; difference the second conducting main strips of each of the touch electrode structure are respectively connecting to difference signal lines by the correspondingly switch, and the second conducting main strips in the same line are connecting to same signal line according to each of the correspondingly switch.

The beneficial of this disclosure, which is that reduce complex manufacturing while positioned the touch electrode structure in the OLED display device, and also reduce thickness of the touch display device.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a cross sectional schematic view of a touch display device according to an embodiment of the disclosure;

FIG. 2 is a plan view of a touch electrode structure and an anode according to an embodiment of the disclosure;

FIG. 3 is a structural schematic view of a sensing pad according to another embodiment of the disclosure:

FIG. 4 is an equivalent structural schematic view of a touch electrode structure according to an embodiment of the disclosure; and

FIG. 5 is a driving waveform view of equivalent structure of the touch electrode structure shows in FIG. 4.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

In the drawings, the same reference numerals will be used throughout to designate the same of like elements. It will be understood that, although the terms first, second, etc. may be used hereinto describe various elements, these elements should not be limited by these terms. There terms are only used to distinguish one element from another.

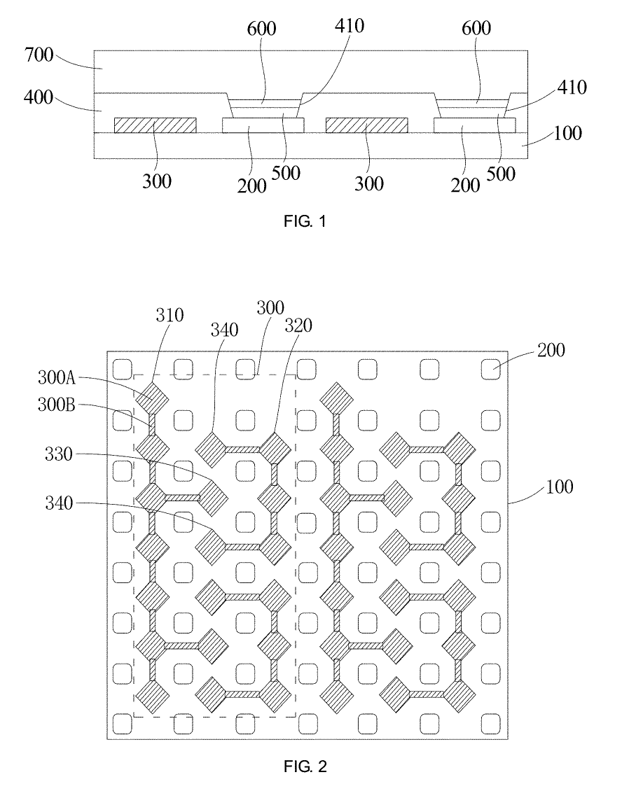

FIG. 1 is a cross sectional schematic view of a touch display device according to an embodiment of the disclosure.

Please refer to FIG. 1, the touch display device of the embodiment in this disclosure includes a substrate 100, an anode 200 is positioned on the substrate 100, a touch electrode structure 300 is positioned on the substrate 100, the touch electrode structure 300 is insulating with the anode 200, a planar layer 400 is positioned on the anode 200, the touch electrode structure 300 and the substrate 100, the planar layer 400 has a hole 410 for exposing the anode 200, an OLED element 500 is positioned on the anode 200, a cathode 600 is positioned on the OLED element 500 and a packaging layer 700 is positioned on the cathode 600 and the planar layer 400.

In addition, it is noted that, before forming the planar layer 400, an insulating protecting layer is forming on the anode 200, the touch electrode structure 300 and the substrate 100 for protecting the anode 200 and the touch electrode structure 300.

Therefore, forming the anode 200 and the touch electrode structure 300 on the same layer, while implant the touch electrode into the OLED display device could also achieves to Incell touch technology, and reduces complex manufacturing, reduces thickness of the touch display device. In addition, because the touch electrode structure 300 is positioned below the OLED element 500 such that it does not need to consider the structure of the touch display, and reduce complex manufacturing.

FIG. 2 is a plan view of a touch electrode structure and an anode according to an embodiment of the disclosure.

Please refer to FIG. 2. The plurality of the anode 200 is provided, the plurality of the touch electrode structure is array arranged, but here is not limited thereto.

The number of the touch electrode structure 300 is two, two of the touch electrode structures 300 are arrange parallel in row direction, and each of the touch electrode structures 200 is extending in column direction. It is notes that, the number of the touch electrode structure 300 is not limited to two, it also could be one, three or more.

Each of the touch electrode structure 300 includes a first conducting main strip 310 is extending along in column direction; a second conducting main strip 320 is extending along in column direction and parallel to the first conducting main strip 310; a first conducting branch strip 330 is extending along in row direction and connecting to the first conducting main strip 310; and at least two second conducting branch strips 340 are extending along in row direction and connecting to the second conducting main strip 320, and at least one of the first conducting branch strip 330 is positioned between two of adjacent second conducting branch strips 340.

It is noted that, the number of the second conducting branch strips 340 which connecting to the second conducting main strip 320 is not limited to two, it also could be one, three or more. In addition, the number of the first conducting branch strips 330 which connecting to the first conducting main strip 310 is not limited to one, it also could be two or more. But there is at least one of the first conducting branch strip 330 is positioned between two adjacent of the second conducting branch strips 340.

In addition, here only illustrates two of the second conducting main strips 320 of each of the touch electrode structure 300, but here is not limited thereto. Each of the touch electrode structures 300 could include three or more of the second conducting main strip 320, each of the second conducting main strips 320 is connecting to at least two of the second conducting branch strips 340.

In each of the touch electrode structure 300, two of the second conducting main strips 320 are parallel along the column direction, and at least one of the first conducting branch strip 330 is positioned between two of adjacent second conducting branch strips 340 which connecting to each of the second conducting main strips 320.

The first conducting main strip 310 and the second conducting main strip 320 both comprise a plurality of sensing pad 300A arranged in column direction and a plurality of bridge connector 300B for connecting in cascade with the sensing pads 300A.

The first conducting branch strip 330 comprises sensing pad 300A and a bridge connector 300B for connecting the sensing pad 300A to the first conducting main strip 310. Here, the first conducting branch strip 330 comprises a sensing pad 300A and a bridge connector 300B. But here is not limited thereto, number of the sensing pad 300A and the bridge connector 300B of the first conducting branch strip 330 could adjust by realistic.

The second conducting branch strip 340 comprises sensing pad 300A and a bridge connector 300B for connecting the sensing pad 300A to the second conducting main strip 320. The sensing pad 33A of the first conducting branch strip 330 is positioned between the sensing pad 300A of two adjacent of the correspondingly the second conducting branch strips 340.

In addition, in this embodiment, the sensing pad 300A is rectangular, but here is not limited thereto. For example, the sensing pad 300A further could be rhombus, triangle, regular pentagon, regular hexagon, octagon or other suitable shaped.

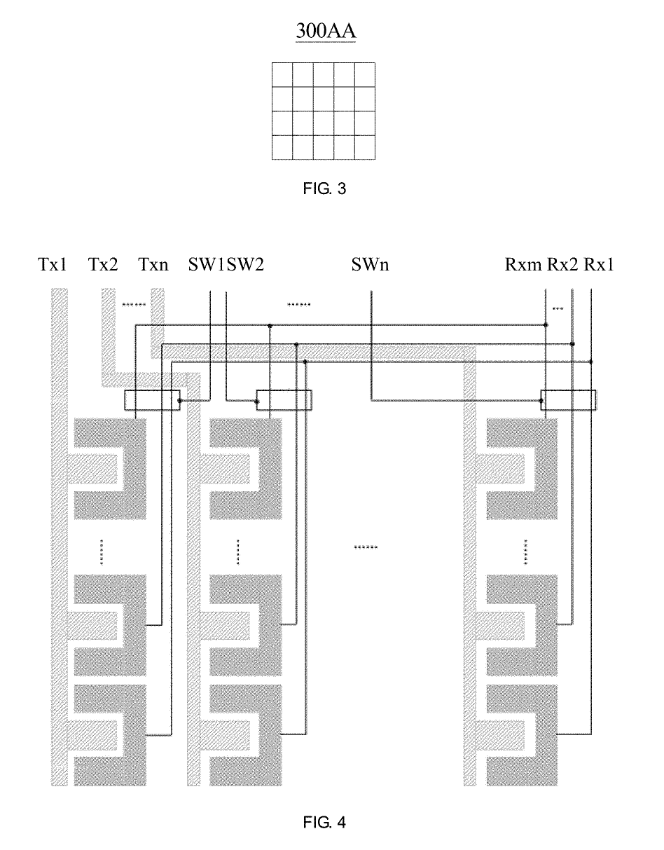

In another embodiment of this invention, please refer to FIG. 3. The sensing pad 300AA further could be grid. While the sensing pad 300AA is grid, the sensing pad 300AA could make by metal, the sensing pad 300AA made by metal grid has feature of high sensitivity, fast response, and it also could reduce cost and decrease difficult manufacturing.

FIG. 4 is an equivalent structural schematic view of a touch electrode structure according to an embodiment of the disclosure.

Please refer to FIG. 4, the touch electrode structure 300 of the FIG. 2 is equivalent to the touch electrode structure AP of the FIG. 4. In the FIG. 4, illustrates n touch electrode structures AP1, AP2 . . . APn. The n touch electrode structures AP1, AP2 . . . APn are parallel arrange along row direction. In addition, FIG. 4 also illustrates n signal lines Txl, Tx2 . . . Txn, m signal lines Rx1, Rx2 . . . Rxm.

In addition, the touch electrode structure APi (1≤i≤n) includes m second conducting main strips 320 are arrange in column direction, such that n touch electrode structures AP1, AP2 . . . APn, n*m second conducting main strips 320 are arrange in array.

The first conducting main strip 310 of the touch electrode structure APi is independently transfer signal, and the first conducting main strip 310 of the touch electrode structure APi is connecting to the correspondingly signal line Txi. According to the touch display device of the embodiment in this disclosure further comprises n switches SW1, SW2 . . . SWn. The switch SWi is corresponding to the touch electrode structure APi, and the m second conducting main strips 320 of the touch electrode structure APi are respective to m signal lines Rx1, Rx2 . . . Rxm by the correspondingly switches SWi. However, the second conducting main strips 320 in the same line are connecting to same signal line according to each of the correspondingly switches. For example, the second conducting main strips 320 in the first line is connecting to the signal line Rxm according to the correspondingly switches SW1, SW2 . . . SWn. But here is not limited thereto.

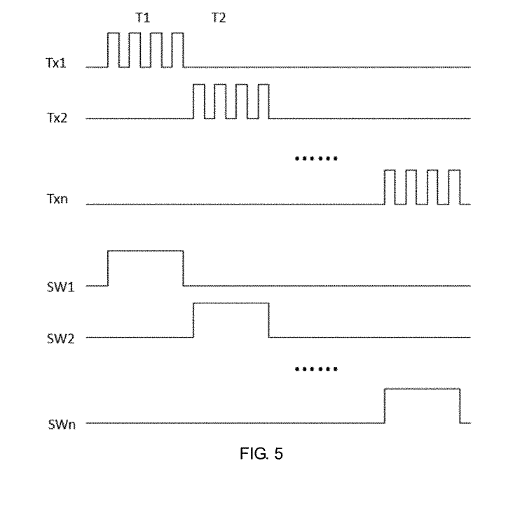

FIG. 5 is a driving waveform view of equivalent structure of the touch electrode structure shows in FIG. 4.

Please refer to FIG. 4 and FIG. 5. In a predetermine time driving the signal line Txi, and switch on the switch SWi such that respectively receiving sensing signals of m second conducting main strips 320 of the touch electrode structure APi according to m signal lines Rx1, Rx2 . . . Rxm, so that finished touch operation. Therefore, driving the signal line Tx1 in the first predetermine time, switch on the switch SWI1 such that respectively receiving sensing signals of m second conducting main strips 320 of the touch electrode structure AP1 according to m signal lines Rxl, Rx2 . . . Rxm. Driving the signal line Tx2 in the second predetermine time, switch on the switch SW2 such that respectively receiving sensing signals of m second conducting main strips 320 of the touch electrode structure AP2 according to m signal lines Rx1, Rx2 . . . Rxm. And so on, therefore finished sensing driving and detecting of touch for n touch electrode structure AP1, AP2 . . . . APn. That is, only switch on i^{th} switch SWi in a predetermine time could avoid noise from other sensing line.

In sum, these embodiments of the disclosure could reduce complex manufacturing while positioned the touch electrode structure in the OLED display device, and also reduce thickness of the touch display device.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A touch display device, comprising
a substrate;
an anode positioned on the substrate;
a touch electrode structure positioned on the substrate, the touch electrode structure is insulating with the anode;
a planar layer positioned on the anode, the touch electrode structure and the substrate, the planar layer has a hole for exposing the anode;
an OLED element positioned on the anode;
a cathode positioned on the OLED element; and
a packaging layer positioned on the cathode and the planar layer.

2. The touch display device according to claim 1, wherein a plurality of the touch electrode structure is provided, the plurality of the touch electrode structure is arranges parallel in row direction, and each of the touch electrode structures is extending in column direction.

3. The touch display device according to claim 2, wherein each of the touch electrode structures comprising
a first conducting main strip extending along in column direction;
a second conducting main strip extending along in column direction and parallel to the first conducting main strip;
a first conducting branch strip extending along in row direction and connecting to the first conducting main strip; and
at least two second conducting branch strips extending along in row direction and connecting to the second conducting main strip, and at least one of the first conducting branch strip is positioned between two of adjacent second conducting branch strips.

4. The touch display device according to claim 3, wherein each of the touch electrode structure has a plurality of the second conducting main strip, a plurality of the second conducting main strip is parallel along the column direction, and at least one of the first conducting branch strip is positioned between two of adjacent second conducting branch strips which connecting to each of the second conducting main strips.

5. The touch display device according to claim 3, wherein the first conducting main strip comprises a plurality of sensing pad arranged in column direction and a bridge connector for connecting in cascade with the sensing pad.

6. The touch display device according to claim 3, wherein the second conducting main strip comprises a plurality of sensing pad arranged in column direction and a bridge connector for connecting in cascade with the sensing pad.

7. The touch display device according to claim 3, wherein the first conducting branch strip comprises a sensing pad and a bridge connector for connecting the sensing pad to the first conducting main strip.

8. The touch display device according to claim 7, wherein the second conducting branch strip comprises a sensing pad and a bridge connector for connecting the sensing pad to the second conducting main strip, the sensing pad of the first conducting branch strip is positioned between two of adjacent correspondingly the second conducting branch strips.

9. The touch display device according to claim 5, wherein the sensing pad is one of rectangular, grid, rhombus, triangle, regular pentagon, regular hexagon, octagon.

10. The touch display device according to claim 6, wherein the sensing pad is one of rectangular, grid, rhombus, triangle, regular pentagon, regular hexagon, octagon.

11. The touch display device according to claim 7, wherein the sensing pad is one of rectangular, grid, rhombus, triangle, regular pentagon, regular hexagon, octagon.

12. The touch display device according to claim 8, wherein the sensing pad is one of rectangular, grid, rhombus, triangle, regular pentagon, regular hexagon, octagon.

13. The touch display device according to claim 4, wherein all of the second conducting main strips of the touch electrode structures are arranged in array; the touch display device further comprises a plurality of switches, each of the switches corresponding to one of the touch electrode structure; difference the second conducting main strips of each of the touch electrode structures are respectively connecting to difference signal lines by the correspondingly switch, and the second conducting main strips in the same line are connecting to same signal line according to each of the correspondingly switch.
